(19) United States
(12) Patent Application Publication
(10) Pub. No.: US 2025/0176390 A1
(43) Pub. Date: May 29, 2025

(54) DISPLAY PANEL AND FABRICATION METHOD THEREOF, AND DISPLAY DEVICE

(71) Applicant: Wuhan Tianma Micro-Electronics Co., Ltd., Wuhan (CN)

(72) Inventor: Shaoya QIU, Wuhan (CN)

(21) Appl. No.: 18/627,149

(22) Filed: Apr. 4, 2024

(30) Foreign Application Priority Data
Nov. 27, 2023 (CN) 202311605752.6

(51) Int. Cl. H10K 59/35; H10K 71/16

(52) U.S. Cl. CPC H10K 59/353; H10K 59/352; H10K 71/166

(57) ABSTRACT

A display panel and its fabrication method, and a display device are provided. The display panel includes pixels. Each pixel includes a first color sub-pixel, a second color sub-pixel and a third color sub-pixel, arranged in a triangle. Two pixels adjacent along a matrix row direction form a pixel group including a first pixel and a second pixel. Two adjacent matrix rows include an n-th row and an (n+1)-th row. Pixel groups in the n-th row and pixel groups in the (n+1)-th row are offset, such that first pixels of the n-th row and second pixels of the (n+1)-th row are located in a same matrix column. Along the matrix row direction and/or the matrix column direction, at least part of the sub-pixels of the same color in the adjacent pixels are arranged adjacently, and light-emitting layers of the sub-pixels of the same color in the adjacent pixels are connected.

### CROSS-REFERENCE TO RELATED APPLICATION

This application claims the priority of Chinese Patent Application No. 202311605752.6, filed on Nov. 27, 2023, the content of which is incorporated herein by reference in its entirety.

### TECHNICAL FIELD

The present disclosure generally relates to the field of display technology and, more particularly, relates to a display panel and its fabrication method, and a display device.

### BACKGROUND

An aperture ratio is one of important factors to measure display effect of a display panel. When the aperture ratio of the display panel is higher, the efficiency of light passing through is higher and the display effect is better.

However, in an evaporation process of light-emitting materials of an organic light-emitting diode (OLED), each color sub-pixel is usually evaporated using different evaporation openings of a mask, and it is necessary to reserve an evaporation margin between different evaporation openings to avoid overlapping and mixing of organic materials of different colors, which increases an area of a non-light-emitting area in the display panel, thereby limiting the improvement of the aperture ratio and affecting the display effect and product life.

### SUMMARY

One aspect of the present disclosure provides a display panel. The display panel includes a plurality of pixels. Each of the plurality of pixels includes a first color sub-pixel, a second color sub-pixel and a third color sub-pixel, wherein the first color sub-pixel, the second color sub-pixel and the third color sub-pixel are arranged to form a triangle. Two pixels of the plurality of pixels adjacent along a matrix row direction form a pixel group including a first pixel and a second pixel. Two adjacent matrix rows include an n-th row and an (n+1)-th row, wherein pixel groups in the n-th row and pixel groups in the (n+1)-th row are offset, such that first pixels of the n-th row and second pixels of the (n+1)-th row are located in a same matrix column, with n being a positive integer; and along the matrix row direction and/or the matrix column direction, at least part of sub-pixels of the same color in adjacent pixels are arranged adjacently, and light-emitting layers of the sub-pixels of the same color in the adjacent pixels are connected.

Another aspect of the present disclosure provides a fabrication method of a display panel. The method includes: providing a motherboard; and using masks to form light-emitting layers on the motherboard, to form a plurality of pixels and obtain the display panel. Each of the plurality of pixels includes a first color sub-pixel, a second color sub-pixel and a third color sub-pixel, wherein the first color sub-pixel, the second color sub-pixel and the third color sub-pixel are arranged to form a triangle. Two pixels of the plurality of pixels adjacent along a matrix row direction form a pixel group including a first pixel and a second pixel. Two adjacent matrix rows include an n-th row and an (n+1)-th row, wherein pixel groups in the n-th row and pixel groups in the (n+1)-th row are offset, such that first pixels of the n-th row and second pixels of the (n+1)-th row are located in a same matrix column, and n is a positive integer; and light-emitting layers of the sub-pixels of the same color in the adjacent pixels are connected

Another aspect of the present disclosure provides a display device. The display device includes a display panel. The display panel includes a plurality of pixels. Each of the plurality of pixels includes a first color sub-pixel, a second color sub-pixel and a third color sub-pixel, wherein the first color sub-pixel, the second color sub-pixel and the third color sub-pixel are arranged to form a triangle. Two pixels of the plurality of pixels adjacent along a matrix row direction form a pixel group including a first pixel and a second pixel. Two adjacent matrix rows include an n-th row and an (n+1)-th row, wherein pixel groups in the n-th row and pixel groups in the (n+1)-th row are offset, such that first pixels of the n-th row and second pixels of the (n+1)-th row are located in a same matrix column, with n being a positive integer; and along the matrix row direction and/or the matrix column direction, at least part of sub-pixels of the same color in adjacent pixels are arranged adjacently, and light-emitting layers of the sub-pixels of the same color in the adjacent pixels are connected.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an arrangement structure of a portion of pixels in an exemplary display panel consistent with various disclosed embodiments in the present disclosure;

FIG. 2 illustrates another arrangement structure of a portion of pixels in an exemplary display panel consistent with various disclosed embodiments in the present disclosure;

FIG. 3 illustrates a partial cross-sectional view of an exemplary display panel consistent with various disclosed embodiments in the present disclosure;

FIG. 4 illustrates another partial cross-sectional view of an exemplary display panel consistent with various disclosed embodiments in the present disclosure;

FIG. 5 illustrates another arrangement structure of a portion of pixels in an exemplary display panel consistent with various disclosed embodiments in the present disclosure;

FIG. 6 illustrates another arrangement structure of a portion of pixels in an exemplary display panel consistent with various disclosed embodiments in the present disclosure;

FIG. 7 illustrates another arrangement structure of a portion of pixels in an exemplary display panel consistent with various disclosed embodiments in the present disclosure;

FIG. 8 illustrates another partial cross-sectional view of an exemplary display panel consistent with various disclosed embodiments in the present disclosure;

FIG. 9 illustrates another partial cross-sectional view of an exemplary display panel consistent with various disclosed embodiments in the present disclosure;

FIG. 10 illustrates another arrangement structure of a portion of pixels in an exemplary display panel consistent with various disclosed embodiments in the present disclosure;

FIG. 11 illustrates another arrangement structure of a portion of pixels in an exemplary display panel consistent with various disclosed embodiments in the present disclosure;

FIG. 12 illustrates a relative position and structure of evaporation openings and an evaporation area of a mask consistent with various disclosed embodiments in the present disclosure;

FIG. 13 illustrates another arrangement structure of a portion of pixels in an exemplary display panel consistent with various disclosed embodiments in the present disclosure;

FIG. 14 illustrates another arrangement structure of a portion of pixels in an exemplary display panel consistent with various disclosed embodiments in the present disclosure;

FIG. 15 illustrates another arrangement structure of a portion of pixels in an exemplary display panel consistent with various disclosed embodiments in the present disclosure;

FIG. 16 illustrates another arrangement structure of a portion of pixels in an exemplary display panel consistent with various disclosed embodiments in the present disclosure;

FIG. 17 illustrates another arrangement structure of a portion of pixels in an exemplary display panel consistent with various disclosed embodiments in the present disclosure;

FIG. 18 illustrates a flowchart of a fabrication method of a display panel consistent with various disclosed embodiments in the present disclosure;

FIG. 19 illustrates a relative position and structure of evaporation openings and an evaporation area of another mask consistent with various disclosed embodiments in the present disclosure;

FIG. 20 illustrates another relative position and structure of evaporation openings and an evaporation area of a mask consistent with various disclosed embodiments in the present disclosure;

FIG. 21 illustrates a relative position and structure of evaporation openings and an evaporation area of another mask consistent with various disclosed embodiments in the present disclosure; and

FIG. 22 illustrates a relative position and structure of evaporation openings and an evaporation area of another mask consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

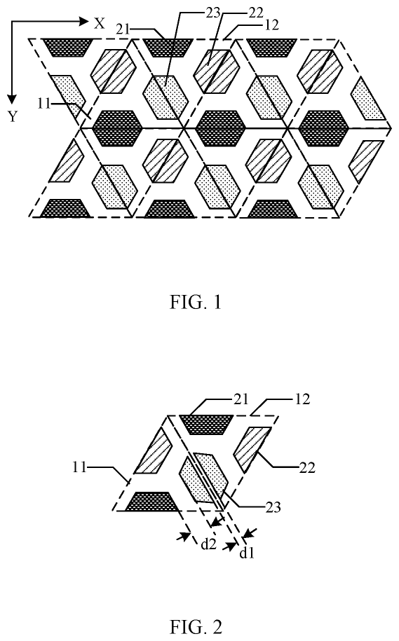

The present disclosure provides a display panel. As shown in FIG. 1, in one embodiment, the display panel may include a plurality of pixels 11 and 12. The plurality of pixels may be arranged in a matrix. Each pixel of the plurality of pixels may include a first-color sub-pixel 21, a second-color sub-pixel 22, and a third-color sub-pixel 23. The first-color sub-pixel 21, the second-color sub-pixel 22, and the third-color sub-pixel 23 may be arranged in a triangle.

In one embodiment, edges or extension lines of edge tangents of the first color sub-pixel 21, the second color sub-pixel 22 and the third color sub-pixel 23 closest to the outside of the pixels may form a triangle (shown by the dotted line in FIG. 1).

As shown in FIG. 1, a row of the matrix may extend along a X direction, and a matrix of the matrix may extend along a Y direction. Along the matrix row direction, two adjacent pixels may form a pixel group, and each pixel group may include a first pixel 11 and a second pixel 12. Two adjacent matrix rows may include the n-th row and the (n+1)-th row, and the pixel groups of the n-th row and the pixel groups of the (n+1)-th row may be offset such that the first pixels of the n-th row and the second pixels of the (n+1)-th row are located at the same matrix column, where n is a positive integer.

For example, as shown in FIG. 1, for the first pixel 11 labelled in FIG. 1, the second pixel which forms one pixel group with the first pixel 11 may be the second pixel 12 on the right side of the first pixel 11 as labelled in FIG. 1 or the second pixel 12 on the left side of the first pixel 11, which is not limited in the present disclosure. For description purposes only, the embodiment where the first pixel 11 labelled in FIG. 1 and the second pixel 12 on the right side of the first pixel 11 are considered as one pixel group will be used as an example to illustrate the present disclosure. Those skilled in the art may regard another second pixel 12 adjacent to the first pixel 11 in FIG. 1 and the first pixel 11 as a pixel group without any creative effort, which will not be described again.

Along the row direction and/or the column direction of the matrix, at least a portion of sub-pixels of a same color in adjacent pixels may be arranged adjacent to each other, ad light-emitting layers of sub-pixels of the same color in adjacent pixels may be connected.

As shown in FIG. 1, for example, in one embodiment, in one pixel group, sub-pixles 23 of a third color in the first pixel 11 and the second pixel 12 may be arranged adjacent to each other and the light-emitting layers of the sub-pixels 23 may be connected. In another embodiment, one second pixel 12 in one pixel group and one sub-pixel 22 of a second color in one first pixel 11 in one adjacent pixel group adjacent to the pixel group in the row direction of the matrix may be arranged adjacent to each other and their light-emitting layers may be connected. In another embodiment, one first pixel 11 in one pixel group and one sub-pixel 21 of a first color in one second pixel 12 in one adjacent pixel group in the row direction of the matrix may be arranged adjacent to each other and their light-emitting layers may be connected.

The pixel arrangement method provided by the present disclosure may make full use of the panel space and increase the pixel density, and the sub-pixels of different colors in the display panel may have the same quantity and may be evenly arranged, improving the display effect of the display panel. Further, in the display panel provided by the present disclosure, one sub-pixel in one pixel may be adjacent to one corresponding sub-pixel in another pixel. The light-emitting layers of adjacent sub-pixels of the same color may be connected and share an evaporation opening, which increases the aperture ratio of the display panel, thereby improving the display effect and the life of the display panel.

The size of the evaporation openings of the mask will be larger than the size of the actual evaporated light-emitting layers, that is, there will be an evaporation margin between the light-emitting layers generated using different masks in the display panel. Therefore, multiple sub-pixels sharing one evaporation opening may reduce the existence of evaporation margin and improve the aperture ratio of the display panel. As shown in FIG. 2, a minimum distance between the boundaries of two sub-pixels of the same color and adjacently arranged (that is, generated using a same evaporation opening) may be recorded as the first distance d1, and a minimum distance between the boundaries of two sub-pixels of different colors and adjacently arranged (that is, generated using different evaporation openings) may be recorded as the second distance d2. In some optional embodiments, the first distance d1 may be set to be smaller than the second distance d2, to increase the pixel aperture ratio.

In some embodiments, the first distance d1 may be larger than or equal to 3 μm and less than or equal to 10 μm, and the second distance d2 may be larger than or equal to 15 μm and less than or equal to 25 μm.

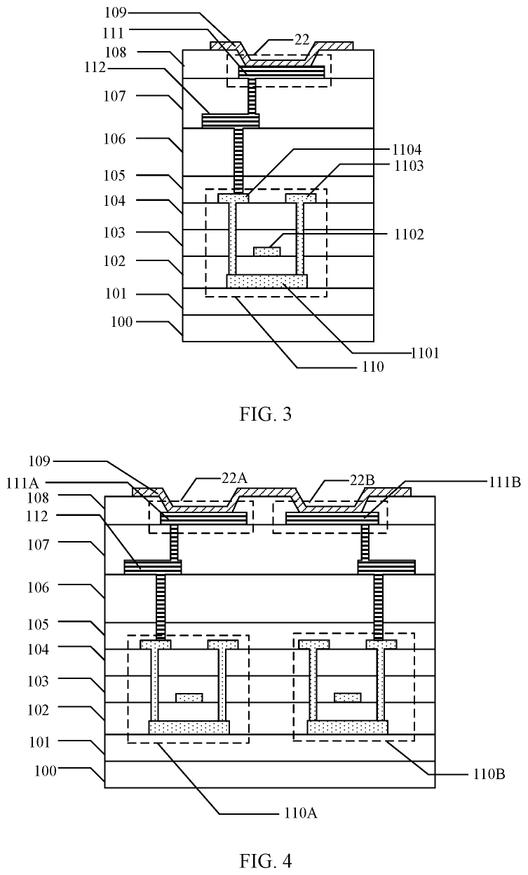

In one embodiment, the pixel area and the light-emitting layer area may be different. When the light-emitting layers of two sub-pixels are connected, when the two sub-pixels electrolight-emittingly emit light, they may appear as two independent sub-pixels. In one embodiment shown in FIG. 3 which is a cross-sectional view of an area of the display panel where a second sub-pixel is located, the film layer structure may include a substrate 100, a buffer layer (Buffer) 101, a gate insulation layer (GI) 102, an interlayer dielectric insulation layer (IMD) 103, an interlayer dielectric layer (ILD) 104, a passivation layer (PV) 105, a first planarization layer (PLN) 106, a second planarization layer 107, a pixel definition layer 108, and a light-emitting layer 109. At the same time, in the above-mentioned film layers, the display panel may also include a pixel driving circuit 110, a metal transfer layer 112 and an anode 111. The pixel driving circuit may include an active layer 1101, a gate electrode 1102, a source 1103 and a drain 1104. As shown in FIG. 3, through the isolation of the pixel definition layer 108, the light-emitting layer 109 may include a part in contact with the anode 111 and another part that is not in contact with the anode 111, and only the part of the light-emitting layer 109 in contact with the anode 111 may be able to electroluminescence and appear as an independent pixel.

In some embodiments, as shown in FIG. 4, the display panel may further include a plurality of anodes. For example, in one embodiment shown in FIG. 4, the display panel may include a first anode 111A and a second anode 111B. Two sub-pixels in adjacent pixels whose light-emitting layers are connected may be connected to different pixel driving circuits through different anodes.

FIG. 4 is a cross-sectional view of the display panel in the area where two second sub-pixels disposed adjacently whose light-emitting layers are connected are located. The light-emitting layer of one second sub-pixel 22A and the light-emitting layer of the other second sub-pixel 22B may be respectively connected to the first anode 111A and the second anode 111B, and then may be respectively connected to the first pixel driving circuit 110A and the second pixel driving circuit 110B through the first anode 111A and the second anode 111B.

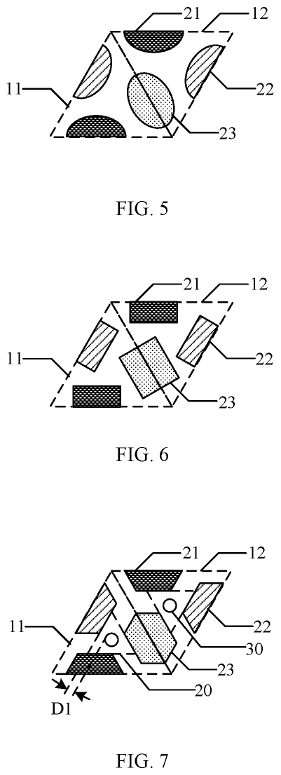

In various embodiments, the shape of each sub-pixel in the display panel may be a trapezoid as shown in FIG. 1 and FIG. 2, a semi-ellipse as shown in FIG. 5, or a rectangle as shown in FIG. 5. The present disclosure has no limit on the shape of the sub-pixels.

In some embodiments, as shown in FIG. 1 and FIG. 2, the shapes of the sub-pixels 21 of the first color, the sub-pixels 22 of the second color, and the sub-pixels 23 of the third color may be isosceles trapezoids, and two sub-pixels in adjacent pixels whose light-emitting layers are connected may form a hexagonal pattern.

In comparison to sub-pixels with other shapes, with a similar size, trapezoidal sub-pixels may occupy a larger area in the pixel, further increasing the aperture ratio of the display panel.

In some embodiment, the sub-pixel 21 of the first color, the sub-pixel 22 of the second color, and the sub-pixel 23 of the third color in one pixel may have light-emitting layers connected to the light-emitting layers of adjacent sub-pixels of same colors respectively.

For example, as shown in FIG. 1, in one embodiment, in the first pixel 11 labelled in FIG. 1, the sub-pixel 21 may be arranged adjacent to the sub-pixel 21 of the first color in the second pixel 12 in another pixel group adjacent along the matrix column direction and their light-emitting layers may be connected, the sub-pixel 22 of the second color may be arranged adjacent to the sub-pixel 22 of the second color in the second pixel 12 in another pixel group adjacent along the matrix column direction and their light-emitting layers may be connected, and the sub-pixel 23 of the third color may be arranged adjacent to the sub-pixel 23 of the third color in the second pixel 12 in another pixel group adjacent along the matrix column direction and their light-emitting layers may be connected. In the second pixel 12 labelled in FIG. 1, the sub-pixel 21 may be arranged adjacent to the sub-pixel 21 of the first color in the first pixel 11 in another pixel group adjacent along the matrix column direction and their light-emitting layers may be connected, the sub-pixel 22 of the second color may be arranged adjacent to the sub-pixel 22 of the second color in the first pixel 11 in another pixel group adjacent along the matrix column direction and their light-emitting layers may be connected, and the sub-pixel 23 of the third color may be arranged adjacent to the sub-pixel 23 of the third color in the first pixel 11 in another pixel group adjacent along the matrix column direction and their light-emitting layers may be connected.

In some embodiments, as shown in FIG. 7, the display panel may further include a plurality of support pillars 30.

One support pillar of the plurality of support pillars 30 may be located in a pixel surrounding area 20 of the sub-pixel 21 of the first color, the sub-pixel 22 of the second color and the sub-pixel 23 of the third color in one corresponding pixel. In the thickness direction of the display panel, the support pillar 30 and the center of the pixel surrounding area 20 may overlap, and the support pillar 30 may not overlap with the sub-pixel 21 of the first color, the sub-pixel 22 of the second color and the sub-pixel 23 of the third color.

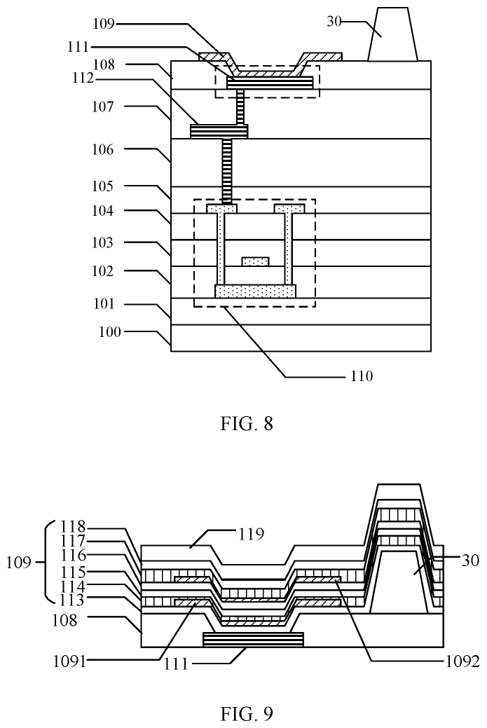

As shown in FIG. 8, the support pillar 30 may be located on a side of the pixel definition layer 108 away from the substrate 100. The support pillar 30 may be formed before the light-emitting layer 109, and may be used to prevent the mask from directly contacting the pixel definition layer 108 during the evaporation process to destroy the pixel definition area. The pixel arrangement of the display panel provided by the present disclosure may make each pixel include a surrounding area surrounded from three sides by the sub-pixels and one support pillar may be set in the middle of the surrounding area. The support pillar may be located in the center of the surrounding area, such that the distance between the support pillar and each sub-pixel may be as far as possible. Therefore, the plane distance from the support pillar to each evaporation opening of the mask may also be as far as possible to avoid the evaporation opening of the mask plate from scratching the support pillar, ensuring the structural strength of the support pillar and improving the yield of the display panel.

Optionally, in one embodiment, the plurality of support pillars 30 may be made of a material including organic materials such as polyimide, and may be formed on the display panel by mask etching.

Optionally, in one embodiment, a height of the plurality of support pillars 30 in the thickness direction of the display panel may be larger than or equal to 2 μm and less than or equal to 4 μm, and the projection of one of the plurality of support pillars 30 on the display panel may completely cover a circle with a diameter larger than or equal to 5 μm.

In one embodiment, as shown in FIG. 9, one light-emitting layer 109 may include a first hole transport layer 113, a first light-emitting material layer 1191, a first electron transport layer 114, a common electrode layer 115, and a second hole transport layer 116, a second light-emitting material layer 1192, a second electron transport layer 117, an electron injection layer 118, and a translucent cathode layer 119. Except for the first light-emitting material layer 1191 and the second light-emitting material layer 1192, the first hole transport layer 113, the first electron transport layer 114, the common electrode layer 115, the second hole transport layer 116, the second electron transport layer 117, the electron injection layer 118 and the translucent cathode layer 119 may be sequentially stacked on one corresponding support pillar 30 and may be formed by full layer evaporation.

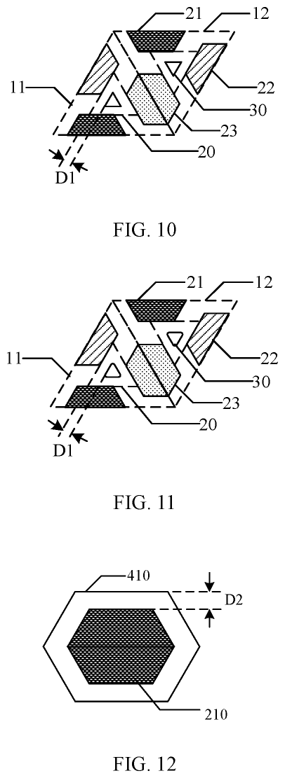

In one embodiment, the shape of the projection of one support pillar 30 on the display panel may be a circle as shown in FIG. 7. In some other embodiments, the shape of the projection of one support pillar 30 on the display panel may also be a triangle as shown in FIG. 10, and the shape may fit the shape of the pixel surrounding area.

In some embodiments, as shown in FIG. 11, in the thickness direction of the display panel, the corners of the side edges of one support pillar 30 adjacent to each sub-pixel may be rounded.

In some embodiments, as shown in FIG. 7, FIG. 10 and FIG. 11, vertical distances D1 between one support pillar 30 and the sub-pixel 21 of the first color, the sub-pixel 22 of the second color and the sub-pixel 23 of the third color in one corresponding pixel may be larger than or equal to 10 μm.

The evaporation margin mentioned in the above embodiments is usually about 10 μm in actual implementation. FIG. 12 shows one evaporation opening 410 of the mask and a corresponding evaporation area 210 corresponding to the evaporation opening 410. A nearest vertical distance D2 from the edges of the evaporation opening 410 of the mask to the edges of the evaporation area 210 may be 10 μm. By making the vertical distances D1 between the support pillar 30 and the sub-pixel 21 of the first color, the sub-pixel 22 of the second color and the sub-pixel 23 of the third color in the corresponding pixel larger than or equal to 10 μm, the projection of the support pillar 30 in the thickness direction and the evaporation opening of the mask may not overlap at all, which prevents the evaporation openings from scratching the support pillar, ensures the structural strength of the support pillar and improves the yield of the display panel.

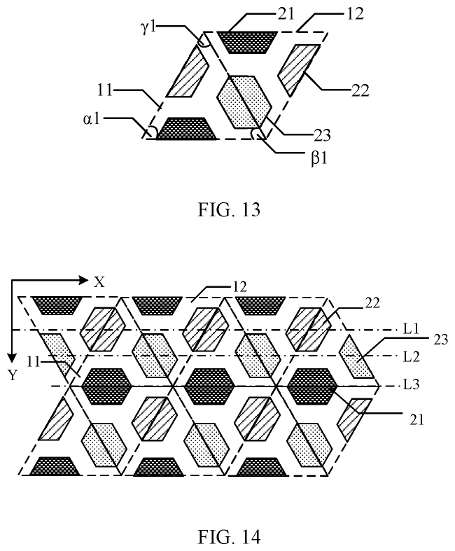

In some embodiments, as shown in FIG. 13, the shapes of the first pixel 11 and the second pixel 12 may both be equilateral triangles, that is, the triangles formed by the first pixel 11 and the second pixel 12 shown in FIG. 13 have three internal angles α2=γ2=β2=60°.

In some embodiments, as shown in FIG. 13, the shape of the first pixel 11 may be a regular equilateral triangle, and the shape of the second pixel 12 may be an inverted equilateral triangle. Both the regular equilateral triangle and the inverted equilateral triangle may be relative to the matrix column direction.

In some embodiments, as shown in FIG. 13, a side edge of the sub-pixel 21 of the first color, a side edge of the sub-pixel 22 of the second color, and a side edge of the sub-pixel 23 of the third color may be respectively parallel to and at least partially overlap with extending directions of three side edges of the equilateral triangle, thereby maximizing the area in a single pixel that each sub-pixel is able to utilize.

In some embodiments, as shown in FIG. 13, the shapes of the sub-pixel 21 of the first color, the sub-pixel 22 of the second color, and the sub-pixel 23 of the third color may be isosceles trapezoids, and the bases of the isosceles trapezoids may be parallel to and at least partially overlap with the extending direction of the side edges of the equilateral triangle.

In some embodiments, as shown in FIG. 13, two sub-pixels in adjacent pixels whose light-emitting layers are connected may form a hexagonal pattern.

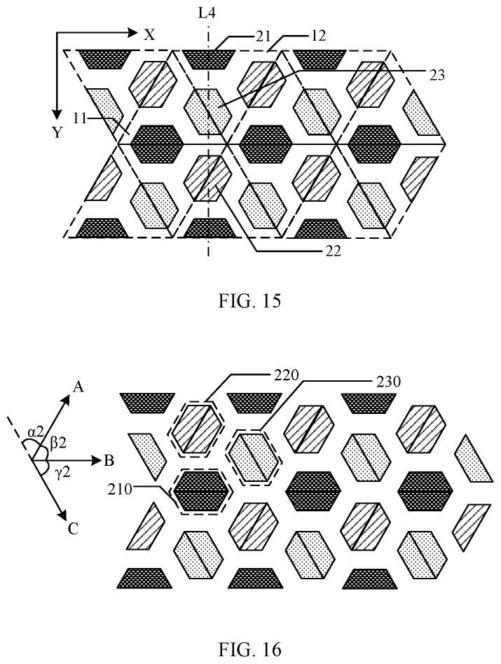

In some embodiments, as shown in FIG. 14, along the matrix row direction (i.e., the X direction in FIG. 14), the centers of sub-pixels of different colors may be located on different straight lines. As shown in FIG. 15, along the matrix column direction (i.e., the Y direction in FIG. 15), the centers of sub-pixels of different colors may be located on the same straight lines.

For example, in one embodiment, as shown in FIG. 14, along the matrix row direction, the center of the sub-pixel 21 of the first color may be located on a straight line L3, the center of the sub-pixel 22 of the second color may be located on the straight line L1, and the center of the sub-pixel 23 of the third color may be located on the straight line L2.

For example, in one embodiment, as shown in FIG. 15, along the matrix column direction, the centers of at least two sub-pixels 21 of the first color, at least two sub-pixels 22 of the second color and at least two sub-pixels 23 of the third color may be all located on the straight line L4.

In some embodiments, as shown in FIG. 16, the positions of the sub-pixels whose light-emitting layers are connected in adjacent pixels may be evaporation areas. The display panel may include first color light-emitting layer evaporation areas 210, second color light-emitting layer evaporation areas 220 and third color light-emitting layer evaporation areas 230. The first color light-emitting layer evaporation areas 210 may have the same color as the first sub-pixel in each pixel, the second color light-emitting layer evaporation areas 220 may have the same as the color of the first sub-pixel in each pixel, and the third color light-emitting layer evaporation areas 230 may have the same color as the third sub-pixel in each pixel. The first color light-emitting layer evaporation areas 210 may be arranged along a first direction (a direction B shown in FIG. 16), the second color light-emitting layer evaporation areas 220 may be arranged along a second direction (a direction A shown in FIG. 16), and the third color emitting layer evaporation areas 230 may be arranged along a third direction (a direction C shown in FIG. 16). The first direction, the second direction and the third direction may intersect each other.

In some embodiments, an included angle between the first direction, the second direction and the third direction may be 60°.

The angle between any two directions may be an acute angle of the two angles formed by the intersection of the two directions. As shown in FIG. 16, the angle between the direction A and the direction C is α2, and the angle between the direction B and the direction C is γ2, and the angle between the direction B and the direction A is β2, where α2=γ2=β2-60°.

In some embodiments, as shown in FIG. 16, centers of three adjacent evaporation areas of the same color light-emitting layers may form a virtual triangle, and the virtual triangle may be an equilateral triangle. Three adjacent same-color emitting layer evaporation areas may include two adjacent same-color emitting layer evaporation areas in the matrix row direction, and another same-color light-emitting layer evaporation area nearset on a center line of a line connecting the two adjacent same-color emitting layer evaporation areas.

In some embodiments, areas of the first color sub-pixels in at least two pixels may be the same, areas of the second color sub-pixels in at least two pixels may be substantially equal, and areas of the third color sub-pixels in at least two pixels may be the same.

In each pixel, pixels of different colors may have the same area to ensure uniform display of the display panel. In one embodiment, in the display panel, the first color sub-pixels in all pixels may have the same area, the second color sub-pixels in all pixels may have the same area, and the third color sub-pixels in all pixels may have the same area.

In some embodiments, one first color sub-pixel, one second color sub-pixel and one third color sub-pixel may respectively include one of green organic light-emitting material, red organic light-emitting material and blue organic light-emitting material.

In one embodiment, the first color sub-pixel may include a blue organic light-emitting material, the second color sub-pixel may include a green organic light-emitting material, and the third color sub-pixel may include a red organic light-emitting material, to form an RGB three-color pixel array.

In some embodiment, the area of each sub-pixel in each pixel may be set according to the light-emitting efficiency of the light-emitting material itself. For example, when the light-emitting efficiency of one material is higher, the area of one corresponding sub-pixel may be smaller. When the light-emitting efficiency of one material is lower, the area of one corresponding sub-pixel may be larger

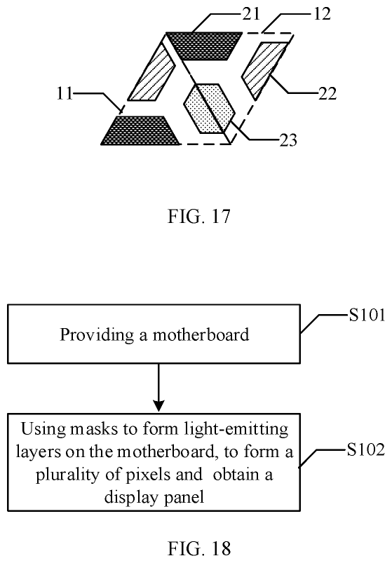

The light-emitting efficiency of the red organic light-emitting material is higher than the light-emitting efficiency of the green organic light-emitting material and the light-emitting efficiency of the green organic light-emitting material is higher than that of the blue organic light-emitting material, in some embodiments, as shown in FIG. 17, the first color sub-pixel 21 may include the blue organic light-emitting material, the second color sub-pixel 22 may include the green organic light-emitting material, and the third color sub-pixel 23 may include the red organic light-emitting material. In one pixel, the area of the first color sub-pixel 21 may be larger than the area of the second color sub-pixel 22 and the area of the second color sub-pixel 22 may be larger than the area of the third color sub-pixel 23.

In some embodiment, the area of each sub-pixel in each pixel may be set according to the material life of the corresponding light-emitting material. For example, when the material life of one material is higher, the area of one corresponding sub-pixel may be smaller. When the material life of one material is lower, the area of one corresponding sub-pixel may be larger

The material life of the red organic light-emitting material is higher than the material life of the green organic light-emitting material and the material life of the green organic light-emitting material is higher than that of the blue organic light-emitting material, in some embodiments, as shown in FIG. 17, the first color sub-pixel 21 may include the blue organic light-emitting material, the second color sub-pixel 22 may include the green organic light-emitting material, and the third color sub-pixel 23 may include the red organic light-emitting material. In one pixel, the area of the first color sub-pixel 21 may be larger than the area of the second color sub-pixel 22 and the area of the second color sub-pixel 22 may be larger than the area of the third color sub-pixel 23.

In some embodiments, the size of each sub-pixel in each pixel may also be set according to the mask requirements. When the light-emitting efficiency and material life of the green organic light-emitting material, red organic light-emitting material and blue organic light-emitting material are almost the same, in one pixel, the first color sub-pixel, the second color sub-pixel and the third color sub-pixel may have the same shape and size. Therefore, the first color sub-pixel, the second color sub-pixel and the third color sub-pixel may be evaporated by using one same mask (just rotated at different angles), which saves the manufacturing cost of the mask, thereby reducing the overall cost of the product.

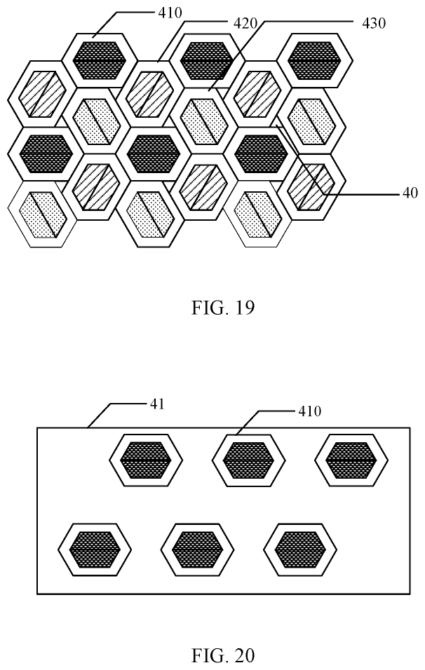

The present disclosure also provides a fabrication method of a display panel. In one embodiment, as shown in FIG. 18, the method may include:
S101: providing a motherboard; and
S102: using a mask to generate light-emitting layers on the motherboard to form a plurality of pixels to obtain a display panel.

The plurality of pixels may be arranged in a matrix. Each pixel of the plurality of pixels may include a first-color sub-pixel, a second-color sub-pixel, and a third-color sub-pixel. The first-color sub-pixel, the second-color sub-pixel, and the third-color sub-pixel may be arranged in a triangle. Along the matrix row direction, two adjacent pixels may form a pixel group, and each pixel group may include a first pixel and a second pixel. The arrangement directions of first pixels and second pixels may be different. Two adjacent matrix rows may include the n-th row and the (n+1)-th row, and the pixel groups of the n-th row and the pixel groups of the (n+1)-th row may be offset such that the first pixels of the n-th row and the second pixels of the (n+1)-th row are located at the same matrix column, where n is a positive integer. At least some of the sub-pixels of the same color in adjacent pixels may share the evaporation opening of the mask.

In the fabrication method of the display panel provided by the present disclosure, the pixel arrangement may make full use of the panel space and increase the pixel density, and the sub-pixels of different colors in the display panel may have the same quantity and may be evenly arranged, improving the display effect of the display panel. Further, in the display panel provided by the present disclosure, one sub-pixel in one pixel may be adjacent to one corresponding sub-pixel in another pixel. The light-emitting layers of adjacent sub-pixels of the same color may be connected and share an evaporation opening, which increases the aperture ratio of the display panel, thereby improving the display effect and the life of the display panel.

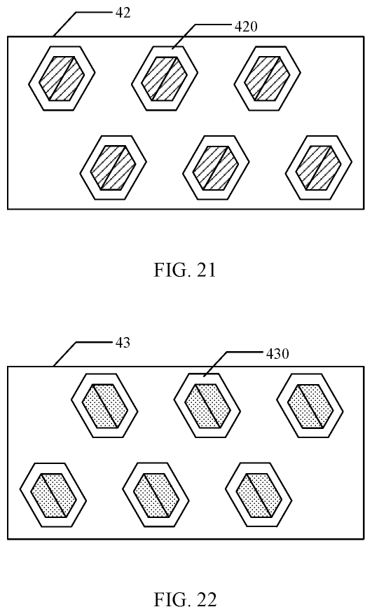

In one embodiment, the mask adopted may have structures shown in FIG. 19 to FIG. 22. FIG. 19 is a schematic diagram of the superimposed masks of each of the three types of sub-pixels. FIG. 20 is a schematic diagram of the first mask 41 corresponding to the first color sub-pixels, including a plurality of first color evaporation openings 410. FIG. 21 is a schematic diagram of the second mask 41 corresponding to the first color sub-pixels, including a plurality of second color evaporation openings 420. FIG. 22 is a schematic diagram of the third mask 43 corresponding to the third color sub-pixels, including a plurality of third color evaporation openings 430. As shown in FIG. 19 to FIG. 22, in the fabrication method of the display panel provided by the present disclosure, because of the unique pixel arrangement, the distance between each evaporation opening in the masks used may be relatively large, which simplifies the fabrication process of the masks and saves production costs.

In some embodiments, when the light-emitting efficiency and material life of the green organic light-emitting material, the red organic light-emitting material and the blue organic light-emitting material are almost the same, in one pixel, the first color sub-pixel, the second color sub-pixel and the third color sub-pixel may have the same shape and size. Therefore, the first mask 41, the second mask 42 and the third mask 43 shown in FIG. 20 to FIG. 22 may use a same mask by rotating at different angles, to evaporate the first color sub-pixel, the second color sub-pixel and the third color sub-pixel, which saves the manufacturing cost of the mask and thereby reduces the overall cost of the product.

In some embodiments, before S102, the method may further includes:

S1011: forming a plurality of support pillars on the motherboard.

As shown in FIG. 8, the plurality of support pillars 30 may be located on a side of the pixel definition layer 108 away from the substrate 100. The plurality of support pillars 30 may be formed before the light-emitting layer 109, and may be used to prevent the mask from directly contacting the pixel definition layer 108 during the evaporation process and destroying pixel-defined areas.

S102 may further includes:

S201: using the plurality of support pillars 30 to support the mask, and using the mask to generate the light-emitting layer on the motherboard. In the thickness direction of the motherboard, at least one of the plurality of support pillars 30 may not overlap any evaporation opening of the mask.

As shown in FIG. 19, after the masks of each of the three types of sub-pixels are superimposed, the projection on the display panel may include a spare area 40 that does not overlap with any evaporation openings. This area may be used to form plurality of support pillars to prevent the evaporated openings from scratching the plurality of support pillars 30, ensuring the structural strength of the plurality of support pillars 30 and improve the display panel yield.

In one embodiment, as shown in FIG. 7, one support pillar 30 of the plurality of support pillars 30 may be located in the pixel surrounding area 20 of the first color sub-pixel 21, the second color sub-pixel 22 and the third color sub-pixel 23 of one corresponding pixel, and, in the thickness direction of the display panel, the support pillar 30 may overlap the center point of pixel surrounding area 20. Other structures for supporting 30 may refer to the embodiments shown in FIGS. 7 to 11.

In one embodiment, the plurality of support pillars 30 may be made of a material including organic materials such as polyimide. S1011 may include: forming a support pillar material layer on the display panel, and performing mask etching on the support pillar material layer to obtain the plurality of support pillars.

In one embodiment, the height of the plurality of support pillars 30 in the thickness direction of the display panel may be larger than or equal to 2 μm and less than or equal to 4 μm. A projection of the plurality of support pillars 30 on the display panel may completely cover a circle with a diameter of larger than or equal to 5 μm.

In one embodiment, a shortest distance between any two evaporation openings in the first mask, the second mask and the third mask may be larger than or equal to 15 μm.

In one embodiment, the aspect ratio of the evaporation openings in the first mask the first mask, the second mask and the third mask may be smaller than or equal to 1.5.

In one embodiment, in the embodiment shown in FIG. 19, the projections of the evaporation openings of the masks of the three types of sub-pixels may be adjacent to each other on the display panel to ensure a higher aperture ratio. In another embodiment, because of the existence of evaporation margin, the projections of the evaporation openings of the masks of the three types of sub-pixels on the display panel may partially overlap.

The present disclosure also provides a display device. The display device may include a display panel provided by various embodiments of the present disclosure.

The display device in various embodiments may be an organic light-emitting diode (OLED) display device, a quantum dot light-emitting diode (QLED) display device, or a micro-OLED/LED display device.

The display device provided by the present disclosure may be applied to a cell phone or any other electronic products with display functions, including but not limited to: TVs, laptops, desktop monitors, tablets, digital cameras, smart bracelets, smart glasses, vehicle monitors, medical equipment, industrial control equipment, e-reader, smart watches, or touch interactive terminals.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising a plurality of pixels arranged in a matrix, wherein:
each of the plurality of pixels includes a first color sub-pixel, a second color sub-pixel and a third color sub-pixel, wherein the first color sub-pixel, the second color sub-pixel and the third color sub-pixel are arranged to form a triangle,
two pixels of the plurality of pixels adjacent along a matrix row direction form a pixel group including a first pixel and a second pixel;
two adjacent matrix rows include an n-th row and an (n+1)-th row, wherein pixel groups in the n-th row and pixel groups in the (n+1)-th row are offset, such that first pixels of the n-th row and second pixels of the (n+1)-th row are located in a same matrix column, with n being a positive integer; and
along the matrix row direction and/or the matrix column direction, at least part of sub-pixels of the same color in adjacent pixels are arranged adjacently, and light-emitting layers of the sub-pixels of the same color in the adjacent pixels are connected.

2. The display panel according to claim 1, wherein:
the first color sub-pixel, the second color sub-pixel and the third color sub-pixel in one pixel are connected to the light-emitting layers of adjacent sub-pixels of the same colors respectively.

3. The display panel according to claim 1, further including a plurality of support pillars, wherein:
one support pillar of the plurality of support pillars is located in a pixel surrounding area formed by the first color sub-pixel, the second color sub-pixel and the third color sub-pixel in one corresponding pixel;
in a thickness direction of the display panel, the support pillar overlaps a center point of the pixel surrounding area; and
the support pillar does not overlap the first color sub-pixel, the second color sub-pixel and the third color sub-pixel.

4. The display panel according to claim 3, wherein:
in the thickness direction of the display panel, the support pillar has a shape matching a shape of the pixel surrounding area.

5. The display panel according to claim 3, wherein:
vertical distances between the support pillar and the first color sub-pixel, the second color sub-pixel and the third color sub-pixel are larger than or equal to 10 μm.

6. The display panel according to claim 1, wherein:
the shapes of the first pixel and the second pixel are both equilateral triangles.

7. The display panel according to claim 6, wherein:
the shape of the first pixel is an equilateral triangle, and the shape of the second pixel is an inverted equilateral triangle.

8. The display panel according to claim 6, wherein:
one side edge of the first color sub-pixel, one side edge of the second color sub-pixel and one side edge of the third color sub-pixel are respectively paralled to and at least partilly overlap extending directions of the three side edges of the equilateral triangle respectively.

9. The display panel according to claim 8, wherein:
shapes of the first color sub-pixel, the second color sub-pixel and the third color sub-pixel are isosceles trapezoids, and bases of the isosceles trapezoids are parallel to and at least partially overlap the extension directions of the sides of the equilateral triangle respectively.

10. The display panel according to claim 1, wherein:
along the matrix row direction, centers of sub-pixels of different colors are located on different straight lines; and
along the matrix column direction, centers of sub-pixels of different colors are located on a same straight line.

11. The display panel according to claim 1, wherein:
positions of sub-pixels whose light-emitting layers are connected in adjacent pixels are evaporation areas;
the display panel includes first color light-emitting layer evaporation areas, second color light-emitting layer evaporation areas and third color light-emitting layer evaporation areas;
the first color light-emitting layer evaporation areas are arranged along afirst direction;
the second color light-emitting layer evaporation areas are arranged along a second direction;
the third color light-emitting layer evaporation areas are arranged along a third direction; and
the first direction, the second direction and the third direction intersect each other.

12. The display panel according to claim 11, wherein:
angles between the first direction, the second direction and the third direction are 60°.

13. The display panel according to claim 1, further including a plurality of anodes, wherein:
two sub-pixels whose light-emitting layers are connected in adjacent pixels are connected to different pixel driving circuits through different anodes.

14. The display panel according to claim 1, wherein:
the first color sub-pixels in at least two of the plurality of pixels have a same area;
the second color sub-pixels in at least two of the plurality of pixels have a same area;
and the third color sub-pixels in at least two of the plurality of pixels have a same area.

15. The display panel according to claim 1, wherein:
the first color sub-pixels, the second color sub-pixels and the third color sub-pixels respectively include one of a green organic light-emitting material, a red organic light-emitting material, or a blue organic light-emitting material.

16. The display panel according to claim 1, wherein:
the first color sub-pixels, the second color sub-pixels and the third color sub-pixels respectively include one of a green organic light-emitting material, a red organic light-emitting material, or a blue organic light-emitting material; and
in one pixel, an area of the first color sub-pixel is larger than an area of the second color sub-pixel, and the area of the second color sub-pixel is larger than an area of the third color sub-pixel.

17. The display panel according to claim 1, wherein:
in one pixel, the first color sub-pixel, the second color sub-pixel, and the third color sub-pixel have same shapes and sizes.

18. A fabrication method of a display panel, comprising:
providing a motherboard; and
using masks to form light-emitting layers on the motherboard, to form a plurality of pixels and obtain the display panel,
wherein:
the plurality of pixels is arranged in a matrix:
each of the plurality of pixels includes a first color sub-pixel, a second color sub-pixel and a third color sub-pixel, wherein the first color sub-pixel, the second color sub-pixel and the third color sub-pixel are arranged to form a triangle,
two pixels of the plurality of pixels adjacent along a matrix row direction form a pixel group including a first pixel and a second pixel;
two adjacent matrix rows include an n-th row and an (n+1)-th row, wherein pixel groups in the n-th row and pixel groups in the (n+1)-th row are offset, such that first pixels of the n-th row and second pixels of the (n+1)-th row are located in a same matrix column, and n is a positive integer; and
light-emitting layers of the sub-pixels of the same color in the adjacent pixels are connected.

19. The method according to claim 18, before using the masks to form the light-emitting layers on the motherboard, further including:
forming a plurality of support pillars on the motherboard,
wherein:
using the masks to form the light-emitting layers on the motherboard includes: using the plurality of support pillars to support the masks, and using the masks to form the light-emitting layers on the motherboard, wherein: in the thickness direction of the motherboard, at least one of the plurality of support pillars does not overlap any of evaporation openings of the masks.

20. A display device comprising a display panel including a plurality of pixels arranged in a matrix, wherein:
each of the plurality of pixels includes a first color sub-pixel, a second color sub-pixel and a third color sub-pixel, wherein the first color sub-pixel, the second color sub-pixel and the third color sub-pixel are arranged to form a triangle,
two pixels of the plurality of pixels adjacent along a matrix row direction form a pixel group including a first pixel and a second pixel;
two adjacent matrix rows include an n-th row and an (n+1)-th row, wherein pixel groups in the n-th row and pixel groups in the (n+1)-th row are offset, such that first pixels of the n-th row and second pixels of the (n+1)-th row are located in a same matrix column, and n is a positive integer; and
along the matrix row direction and/or the matrix column direction, at least part of the sub-pixels of the same color in the adjacent pixels are arranged adjacently, and light-emitting layers of the sub-pixels of the same color in the adjacent pixels are connected.
